(19) United States
(12) Patent Application Publication
(10) Pub. No.: US 2021/0194520 A1
(43) Pub. Date: Jun. 24, 2021

(54) METHODS, DEVICES, AND ALGORITHMS FOR THE LINEARIZATION OF NONLINEAR TIME VARIANT SYSTEMS AND THE SYNCHRONIZATION OF A PLURALITY OF SUCH SYSTEMS

(71) Applicant: S9ESTRE, LLC, Amesbury, MA (US)

(72) Inventor: Bernd SCHAFFERER, Amesbury, MA (US)

(73) Assignee: S9ESTRE, LLC, Amesbury, MA (US)

(21) Appl. No.: 16/071,352

(22) PCT Filed: Dec. 9, 2016
(86) PCT No.: PCT/US2016/065910

§ 371 Date: Jul. 19, 2018

Related U.S. Application Data
(60) Provisional application No. 62/280,380, filed on Jan. 19, 2016.

(51) Int. Cl. H04B 1/04; H01Q 3/26; H04L 25/49

(52) U.S. Cl. CPC H04B 1/0475; H04L 25/49; H01Q 3/267

(57) ABSTRACT

Methods, devices and algorithms for the linearization of nonlinear time variant systems and the synchronization of a plurality of such systems. One embodiment includes a transmit path, including the power amplifier, as used in wireless transmit systems. Advances made in CMOS technology, digital to analog converter (DAC) technology make it possible to implement a substantial part of such a system in the digital domain. Additional embodiments include the integration of a substantial part of such a transmit system in a single integrated circuit (IC). A digital implementation allows for linearization of a broad range of nonlinear and time variant effects. Another aspects is the reuse of methods, devices, components and algorithms used for the linearization of a transmit system to synchronize and time align multiple transmit systems.

### CROSS REFERENCE TO RELATED APPLICATION

The present application claims priority to U.S. Provisional Patent Application No. 62/280,380, filed on Jan. 19, 2016, which is hereby fully incorporated herein by reference.

### TECHNICAL FIELD

The invention relates to the generation and synchronization of multiple radio frequency (RF) signals. More specifically, the invention relates to systems for the digital to analog conversion synchronization and linearization of radio frequency signals as used in, but not limited to, wireless and wired transmission systems, beam forming systems, and active antenna arrays.

### BACKGROUND

Modern wireless transmission systems require high linearity, high bandwidth, and high power efficiency to produce radio frequency (RF) signals. The requirements for high linearity and bandwidth are dictated by various wireless communication standards, such as Long-Term Evolution (LTE), Wideband Code Division Multiple Access (WCDMA), and Global System for Mobile Communications (GSM). The bandwidth requirements stem from the higher data-rates expected from these systems. A high output frequency range is required to allow for multi-band operation. The power efficiency requirement comes from the demand for lower operating expenses, longer battery life, and simpler cooling systems.

Designing such wireless transmission systems while simultaneously optimizing all these requirements is a difficult task. Currently available building blocks used to design such systems have many limitations. Overcoming these limitations requires the use of sophisticated correction and compensation techniques.

One such technique is a digital pre-distortion (DPD) system. An implementation of such a DPD system is depicted in FIG. 1. Many of these DPD systems digitally pre-distort a baseband signal S0 before it is converted into analog domain and up-converted to RF domain (See FIG. 1).

With the advent of: 1) high speed digital to analog converters (DACs), providing sampling rates well above 10 Giga samples per second (GSPS) and the necessary resolution to generate analog signals in the frequency range from DC to several GHz; and, 2) deep sub-micron complementary metal-oxide semiconductor (CMOS) processes allowing for power efficient signal processing, wireless transmission systems can be built completely in the digital domain, i.e. the frequency up conversion using a digital up converter (DUC) and the digital pre-distortion (DPD) can be performed in the digital RF domain as shown in FIG. 2.

Pre-distorting the signals in the digital RF domain has many advantages over baseband pre-distortion systems. First, imperfections of the analog modulator, such as clock feed-through and image suppression, which need additional compensation efforts, do not exist. Second, the RF signals in the digital domain can be generated arbitrarily perfect, limited only by the quantization accuracy used to represent the involved signals. Third, the range, flexibility and stability of operation and functions necessary to perform the pre-distortions are easier implemented in the digital domain compared to the analog domain. However, even in advanced low power deep sub-micron CMOS processes, operating digital systems at clock frequencies of several GHz demand efficient implementations of the DUC and DPD in order to stay within a given power budget.

Also, the implementation of the DPD must be flexible enough to compensate for all kinds of distortion effects a wireless transmission system might exhibit. Such distortion effects might include nonlinear static transfer functions, nonlinear dynamic transfer functions, memory effects and hysteresis effects.

Another requirement for wireless transmission systems is the synchronization of multiple individual wireless transmission systems. Active antenna arrays and beam-forming applications rely on synchronization.

Digital synchronization could be achieved by generating digital RF data in a data source block and transmitting it to the individual transmission systems. However, this requires high data-rates on the link between the data source and the transmission system. To lower the data rates only the base band data is usually sent to the transmission system and the modulation to a carrier frequency, the digital up conversion DUC, is performed in the transmission system.

In order to achieve this, the digital subsystems (DUC and DPD engines) must be synchronized. In embodiments of the subject invention, an engine comprises any electronic circuit that produces output signals based on a set of input signals and internal signals. The DUC includes an internal phase accumulator which gets incremented at every clock cycle. The phase accumulator is a system with an internal state. In embodiments of the subject invention, an internal state comprises the status of internal signals at any given time within a system that operates on input signals and internal signals to produce output signals. In order to achieve synchronization, these internal states have to be the same in the individual transmission system. After the digital subsystems are synchronized, the remaining analog parts (DAC, power amplifier (PA), coupling element (CP)) have to be aligned.

Some solutions have been proposed to these technical challenges. As described in U.S. Patent Application Pub. No. 2013/0079060, an active transceiver array for a wireless telecommunications network is one proposed solution. The transceiver array comprises a plurality of calibratable transceiver modules. Each transceiver module comprises a transceiver chain operable to process a primary signal and generate a processed primary signal; a comparator unit operable to compare said primary signal and said processed primary signal to determine a transceiver chain error induced by said transceiver chain in said processed primary signal; and a correction unit which uses the transceiver error to correct said primary signal to be processed by said transceiver chain.

Commonly-owned U.S. Pat. No. 9,300,462 also relates to the generation and synchronization of multiple radio frequency (RF) signals. More specifically, that disclosure relates to systems for the digital to analog conversion synchronization and linearization of radio frequency signals as used in, but not limited to, wireless and wired transmission systems, beam forming systems, and active antenna arrays. The content of U.S. Pat. No. 9,300,462 is incorporated by reference herein in its entirety.

### SUMMARY

The subject invention discloses methods for the generation of time aligned RF signals at the outputs of multiple transmitters based on digital data streams which can arrive at the transmit systems at different times. The digital data stream can be up-converted to a RF signal using digital up converter (DUC). Methods for synchronizing the digital up converters in the individual transmission as well as the synchronization of local oscillators within the transmit systems are disclosed. Further, the subject invention discloses the reuse of an apparatus and method used for pre-distortion to synchronize a plurality of such transmission systems.

In embodiments, a signal processing circuit comprises a local oscillator configured to generate clock signals, a FIFO configured to receive an input data stream and generate a first digital signal, a sync reference generator configured to generate an internal sync signal, an adder configured to combine the internal sync signal and the first digital signal to generate a composite signal, a transmitter configured to receive the composite signal and generate an analog signal, an antenna configured to receive the analog signal and an external sync signal, a coupling element configured to receive the analog signal and the external sync signal and generate an analog receive signal, a receiver configured to receive the analog receive signal and generate a digital receive signal, and a processor configured to receive the digital receive signal and control one or more of the local oscillator, FIFO, adder, transmitter, receiver, and sync reference generator.

In embodiments, the signal processing circuit also includes a data receiver configured to receive a composite data stream with embedded clocking information and generate the input data stream and a data clock signal. In addition, the FIFO includes a write counter and the data clock signal is used to clock the write counter.

In embodiments, the signal processing circuit also includes a digital signal processor configured to receive the composite signal from the adder and generate a second composite signal to be received by the transmitter. The digital signal processor is capable of shifting the signal the second composite signal in time relative to the composite signal.

In embodiments, the signal processing circuit also includes a digital up converter configured to receive the first digital signal from the FIFO and generate a second digital signal wherein the second digital signal is received by the adder.

In embodiments, the signal processing circuit also includes a data receiver configured to receive a frame based data stream comprising one or more frames wherein each of the one or more frames comprises payload data and a phase accumulator value and wherein the digital up converter comprises a phase accumulator and wherein the phase accumulator is updated with the received phase accumulator value.

In embodiments, the interference between the internal sync signal and the external sync signal is observed at the coupling element.

In embodiments, the external sync signal and internal sync signal are designed such that the processor can detect the time relation between the internal sync signal and the external sync signal.

In embodiments, the external sync signal and internal sync signal are designed such that the processor can detect the amount of time shift from the external sync signal to the internal sync signal.

In embodiments, an antenna array comprises a plurality of signal processing units wherein each of the plurality of signal processing units includes a local oscillator configured to generate clock signals and establishes a local time base for the system, a FIFO configured to receive an input data stream and generate a first digital signal, a sync reference generator configured to generate an internal sync signal, an adder configured to combine the internal sync signal and the first digital signal to generate a composite signal, a transmitter configured to receive the composite signal and generate an analog signal, an antenna configured to receive the analog signal and an external sync signal, a coupling element configured the receive the analog signal and the external sync signal and generate an analog receive signal, a receiver configured to receive the analog receive signal and generate a digital receive signal, and a processor configured to receive the digital receive signal and control one or more of the local oscillator, FIFO, adder, transmitter, receiver, and sync reference generator. In embodiments, the internal sync signal of one of the plurality of signal processing circuits can generate the external sync signal for the other signal processing circuits.

In embodiments, the antenna array also includes an array controller. The array controller activates and deactivates the internal sync signals in each of the plurality of signal processing units and instructs each of the plurality of signal processing units to adjust each local oscillator and/or digital signal processor such that the analog signals generated by each of the plurality of signal processing units are time aligned when received by each antennas.

In embodiments, the antenna array is calibrated by designating a master TRX system and one or more slave TRX systems, in the master TRX system, generating an first internal sync signal, adding the first internal sync signal to a first payload to form a first composite signal and transmitting the first composite signal over a first antenna, in each the slave TRX systems, generating a second internal sync signal, receiving over a second antenna the first composite signal, aligning the second internal sync signal to the first internal sync signal and calculating a time offset to achieve maximal interference between the first internal sync signal and the second internal sync signal, adding the second internal sync signal to a second payload signal to form a second composite signal and transmitting the second composite signal over a second antenna and, in the master TRX system, receiving the second composite signal on the first antenna and observing the interference of the first internal sync signal and the second internal sync signal at a point between the first transmitter and the first antenna.

In embodiments the antenna array is further calibrated by, in the master TRX system, adjusting a first time delay until the observed interference between the first sync signal and the second sync signal is at a minimum and recording an adjustment value to the first time delay and, in each of the one or more slave TRX systems, adjusting a second time delay until the observed interference between the second sync signal and the first sync signal is at a minimum and recording an adjustment value to the second time delay, computing, from the adjustment values to the first time delay and the second time delay the time difference between the master TRX system and the slave TRX system and adjusting the delay of each second composite signal accordingly.

### BRIEF DESCRIPTION OF THE DRAWINGS

Advantages of embodiments of the present disclosure will be apparent from the following detailed description of exemplary embodiments thereof, which description should be considered in conjunction with the accompanying drawing, in which:

FIGS. 1-6b depict methods for designing wireless transmissions systems, as described in U.S. Pat. No. 9,300,462.

FIG. 7a is a block diagram of a multiple antenna array transmit receive system, according to an embodiment;

FIG. 7b is a block diagram of a transmitter, according to an embodiment;

FIG. 7c is a timing diagram of signal arriving at the antenna, according to an embodiment;

FIG. 7d is block diagram of a multiple antenna array transmitting receive system using a bus input data architecture, according to an embodiment;

FIG. 7e is a block diagram of multiple transmitter receive systems using data source synchronization, according to an embodiment;

FIG. 7f is a block diagram of multiple transmitter receive systems using over antenna synchronization, according to an embodiment;

FIG. 8a is schematic of a transmit receive system, according to an embodiment;

FIG. 8b is schematic of a transmit receive system, according to an embodiment;

FIG. 9a is schematic of a transmit receive system, according to an embodiment;

FIGS. 9b and 9c are timing diagrams of transmit receive systems, according to embodiments;

FIG. 10a is schematic transmit receive system, according to an embodiment;

FIG. 10b is a timing diagram of a transmit receive system, according to an embodiment.

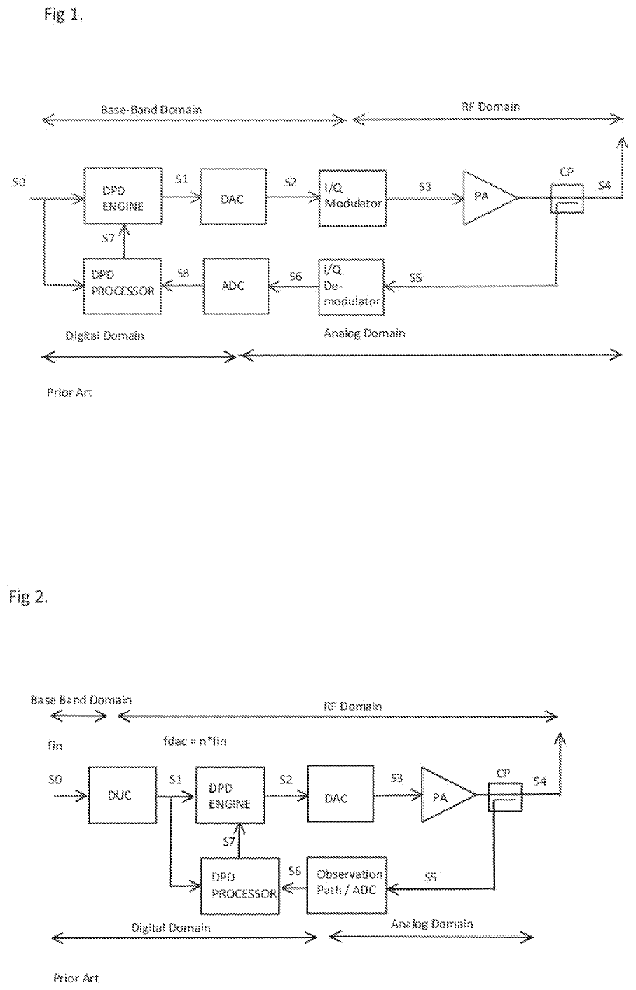

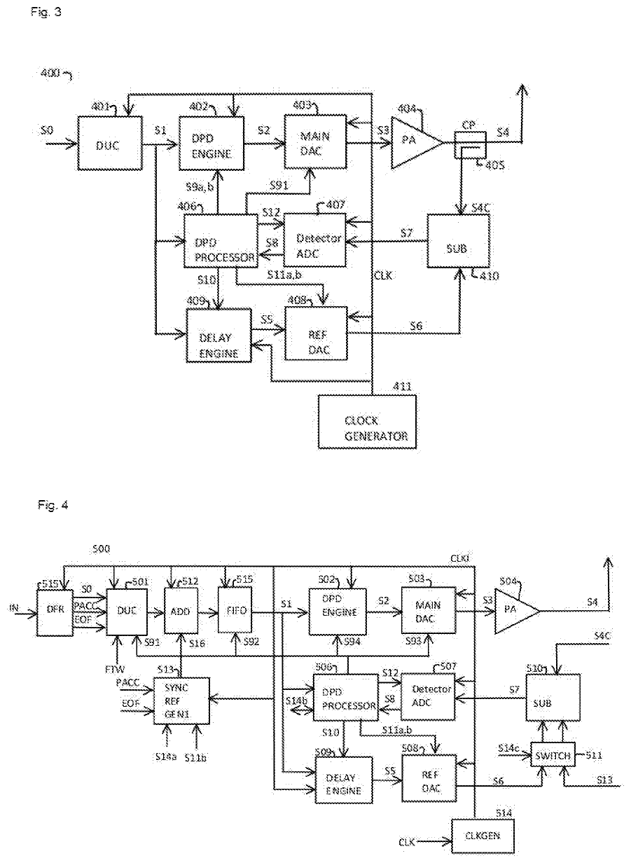

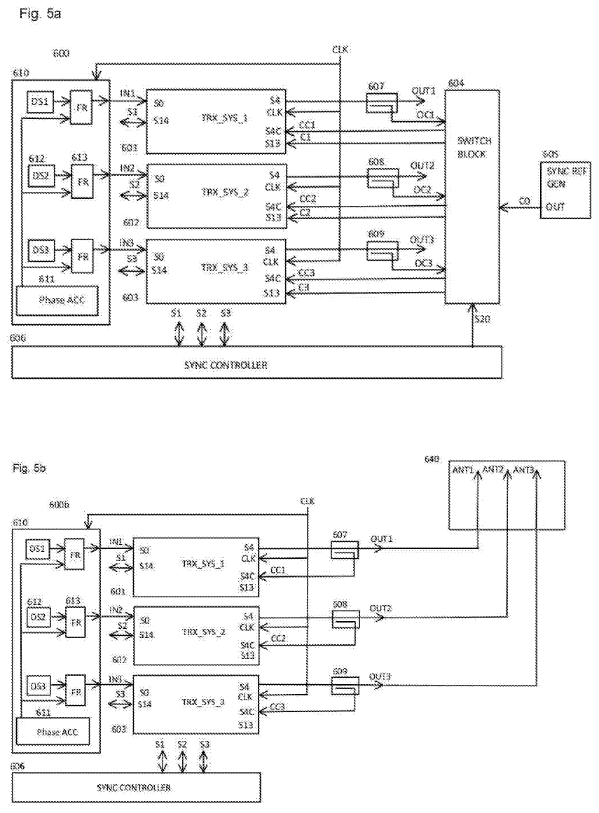

### DETAILED DESCRIPTION

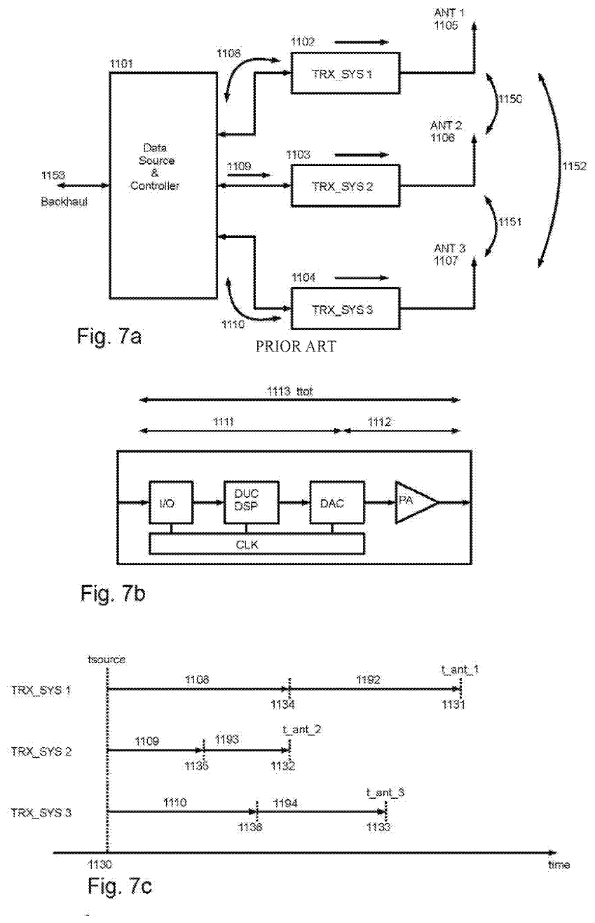

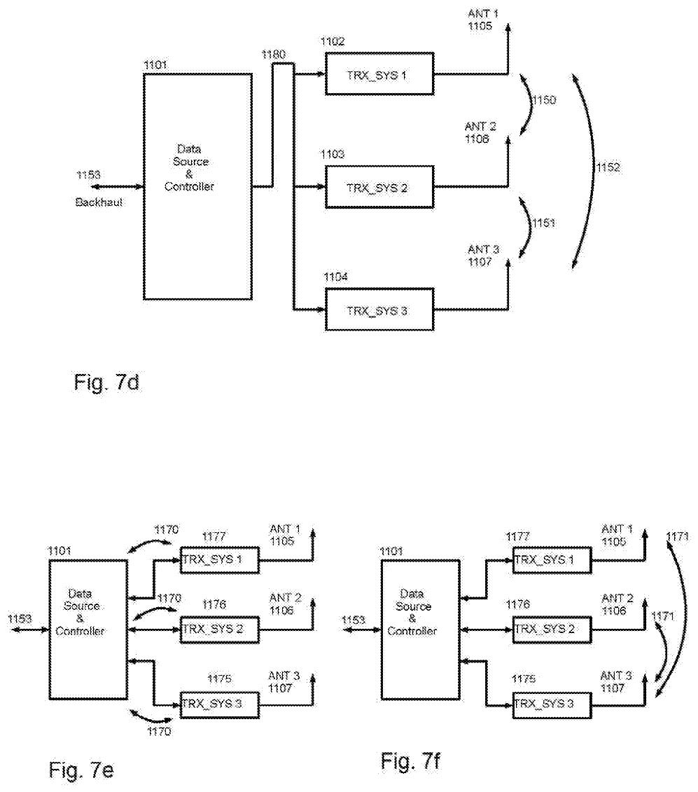

Methods for designing wireless transmissions systems are discussed in U.S. patent application Ser. No. 14/280,574 (the '574 application), entitled “Methods, devices and algorithms for the linearization of nonlinear time variant systems and the synchronization of a plurality of such systems” which is incorporated by reference in its entirety herein. In the description of the following figures, some terminology is used differently as compared to the '574 application. For example, in the context of the description of FIG. 7a et seq., ‘synchronous’ is used to describe that in at least two systems the clocks and/or the internal states of the systems run at the same frequency. However, the signal phases in the individual systems don't have to be time aligned. ‘Time aligned’ is used to describe that in at least two systems the signals within the individual systems change at the same time.

FIG. 7a depicts a common configuration of an antenna array. A common data source 1101 communicates with the individual transmit receive (TRX) systems 1102 to 1104. The transmit systems receive and send digital data to and from the data source 1101. The transmit systems 1102 to 1104 convert the digital data from the data source into signals which can be send to the antennas 1105 to 1107. The data source 1101 processes the data to and from the transmit systems and functions as an interface to the backhaul system 1153. A controller can be used to configure the individual TRX systems. The controller can be a separate block connected to all the TRX systems or the controller can be embedded with the data source 1101. If embedded in the data source the link between the TRX systems and the data source can be frame structured and can also incorporate a command structure which can be interpreted by the processor within the TRX systems. Due to component mismatch and different delay times from the data source 1101 to the individual transmit system 1102 to 1104 the data will not arrive at the same time on the TRX systems 1102 to 1104.

FIG. 7c depicts a timing scenario in a multi TRX system. The data for all TRX systems is generated at the same time 1130. This is a valid assumption since the data source is a digital system it can be designed such that all data will be generated at the same clock cycle. Driver propagation delay mismatches and cable length mismatches will results in different data path delays 1108 to 1110. The data path delays of the TRX systems 1102 to 1104 are adding to the delay of the data paths to the TRX systems 1108 to 1110. The data will arrive at the individual antennas 1105 to 1107 at times 1131 to 1133.

FIG. 7b depicts the transmit path of the TRX system. The transmit path consists of a digital sub system 1111 and an analog sub system 1112. The digital system can consist of an I/O block and digital signals processing block (DSP, DUC). In some systems a first-in-first-out (FIFO) can buffer data between the I/O block and the digital processing block. The FIFO is necessary to avoid setup and hold time violations between the clock domain of the data source and the clock domain of the TRX system. If a FIFO is involved, the propagation delay through the digital sub system might not be deterministic, since the start-up of the read counter and write counter might not be known. Once the signal is processed by the digital subsystem it is passed to the analog subsystem. The analog subsystem will convert the digital signal into an analog RF signal before it is passed to the antenna. The steps of RF modulation, filtering and amplification might be involved in the digital to analog conversion of the signal. These steps will cause propagation delays 1192 to 1194. Due to mismatches the propagation delays 1192 to 1194 of the TRX systems 1102 to 1104 will be different for different TRX systems. The total delay from the generation of the signals in the data source 1130 to the time the signals arrive on the respective antennas 1105 to 1107 is the sum of the delays 1108 to 1110 and the delays of the TRX systems 1192 to 1194.

FIG. 7d, depicts an embodiment where the individual TRX systems are connected to the data source via a bus system 1180. The bus could be a bidirectional serial interface with the individual subsystems as addressable slave devices and the data source as master device. Data throughput, system complexity and cost determine if a bus system can be used to distribute the data to the individual TRX systems. For example, a bus system could be advantageous when baseband data is delivered to the individual TRX systems. Baseband data requires less data throughput than a digital RF signal and would therefore allow for a simpler and more cost efficient bus system.

In general the individual TRX systems will have their own local clock source establishing a local time base for the TRX system. The clock source derives its clocks from a local oscillator. The local clock source can be the time basis for a counter which establishes a local time in the individual TRX systems. A local time can also be established by a phase accumulator. In order to avoid drifting of the local oscillators, the local oscillators are locked in a phase locked loop. The phase locked loop locks the local oscillator frequency to a reference signal which is distributed to the individual TRX systems.

FIG. 7e depicts a scenario in which the reference signal 1170 originates from the data source 1101. The clock signal can be embedded in the data signal or can be a dedicated clock signal. And the alignment of the TRX system is done via the antenna array.

FIG. 7f depicts a scenario in which the reference signal 1171 is distributed via the antenna array. A master TRX system 1175 will generate a RF reference signal and broadcast it within the antenna array. The slave TRX systems 1176, 1177 receive the reference signal and lock their local oscillators to it. Synchronization is different from aligning the output of the antenna arrays relative to each other. Synchronization eliminates the drift of the local oscillators while aligning requires a calibration procedure to adjust for the delays in the TRX systems. Alignment and synchronization can be performed in parallel. The PLL used to lock the local oscillator to a reference signal can be a cascaded PLL or a nested PLL in order to provide additional jitter cleaning of the reference signal 1171.

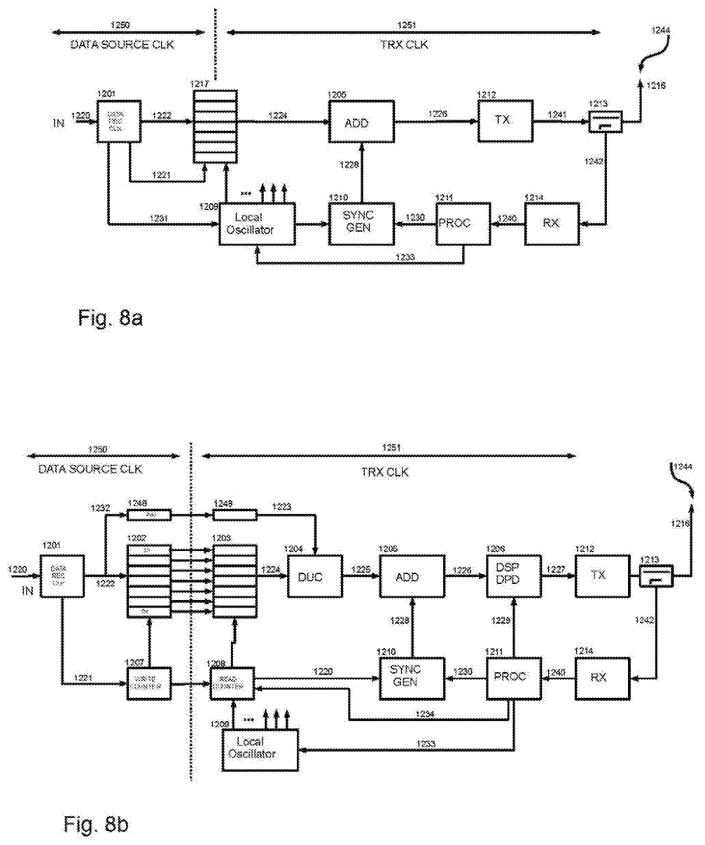

FIG. 8a depicts an embodiment of a TRX system capable of time aligning its output signal to other TRX systems in an antenna array. An input data stream 1220 contains the data and clocking information for the TRX system. The data stream 1220 is received by a data receiver 1201. The data receiver 1201 can recover the clock and the data from the data stream 1220. Additionally, framing information can be decoded by the data receiver 1201. To avoid data corruption during the transfer of the data from the data source clock domain 1250 to the TRX clock domain 1251 a FIFO 1217 can be used. In case the data stream is a frame based data stream the input side of the FIFO can be controlled by the clocking information embedded in the data stream and/or a frame structure of the data stream. For example, the first data word in the frame could always be loaded in the first register of the FIFO. This information can be useful when processing the data on the other side of the FIFO 1217. The necessary length of the FIFO 1217 is determined by the maximum time variation the data streams arrive at the individual TRX systems. Worst case calculation including mismatches, temperature, aging and supply drifts will set a lower limit for the length of the FIFO 1217. There are many different possible implementations of an FIFO. In FIG. 8a, for example, the FIFO is implemented as a dual port memory with a read and write counter. During the start-up phase of the TRX system the reference clock 1231 for the local oscillator can be the clock recovered by the data receiver 1201. The write counter of the FIFO 1217 can be set diametric opposite to the read counter of the FIFO. The local oscillator 1209 can be implemented as part of a phase locked loop. In the start-up phase the local oscillator 1209 can receive the reference clock from the data receiver 1201. The local oscillator 1209 provides the clocks and timing information for all the sub-blocks in the TRX clock domain of the TRX system and, therefore, establishes a local time base for the TRX system. The readout counter of the FIFO can also be derived from the local oscillator. The readout counter can be used as a local time for the TRX system. Once the start-up phase has ended and the TRX system is in a steady state the processor 1211 can add a sync signal to the data stream 1224 to form the composite signal 1226. The composite signal 1226 is converted into an analog signal and can be amplified to form the output signal 1241. The output signal 1241 can be sent to the antenna 1216 via a coupling device 1213. An external reference signal 1244 can be coupled into the antenna 1216. The coupling device 1213 is capable to detect the interference behavior of signals going in and out of the antenna 1216 and therefore capable to detect the interference of the internal sync signal 1228 and external sync signal 1244. Receiver 1214 can detect the interference behavior and/or the signals coming from the antenna 1216. The receiver 1214 converts the coupler signal 1242 into a digital signal 1240. The processor 1211 can analyze the signal from the receiver 1214. The analysis can be either in the time domain and/or the frequency domain. Based on the analysis the processor 1211 can generate control signals 1233 for the local oscillator 1209.

Aligning the external sync signal to the internal sync signal can involve:

In a first step, the processor 1211 will try to align the sync signal 1228 with the external sync signal 1244 at the coupling device 1213 by adding the internal sync signal at different times to the data signal.

Once the sync signals are aligned, in a second step, the processor 1211 will switch the control of the local oscillator 1209 from the reference signal 1231 to control signal 1233 provided by the processor 1211. The sync generator 1210, coupling element 1213, processor 1211 and the receiver 1214 will act as a phase detector in a PLL loop. The processor 1211 can act as a controller and based on the evaluation of the signal from the receiver 1240 order the local oscillator 1209 to run either faster or slower such that the internal and external sync signal remain aligned.

FIG. 8b depicts an embodiment of a transmit receive (TRX) system with digital up-conversion.

The clock domain of TRX system 1251 is independent from the clock domain of the data source system 1250. The data source can generate data based on a data source clock. To receive the data in the TRX system correctly the data source clocking information can be embedded in the data signal or provided to the TRX system as a separate signal. A FIFO can be used to assure error free data transfer between the clock domains.

In FIG. 8a the clocking information 1221 and data information 1222 is recovered from the input data stream 1220. In FIG. 8b the data information is further divided into payload data and a phase accumulator value 1232. The phase accumulator value is used to set the phase accumulator in the digital up converter 1204. The clocking information 1221 operates the write counter of a FIFO 1207. The data D1 to Dn is written into the FIFO 1202. The read/write counter length can be a multiple or a sub multiple of the frame length provided by the data source. The read counter can be periodically reset based on a reset signal generated in the data source. The periodic reset assures that the system would recover after a glitch in the system by itself. If a frame structure is used to transmit the data, the frame boundaries could be used to generate the write counter reset signal. In embodiments, a read counter can be adjusted based on the external synchronization signal. Adjusting the read counter allows the processor 1211 to shift the signal at 1227 by one clock cycle. For a fine adjustment of the delay in the sub clock cycle range a digital delay filter in the DSP 1206 can be used. Another option to phase shift signal 1227 is to change the phase of the local oscillator 1209. Another option is to shift the clock operating the digital to analog converter (DAC) within the TX module 1212. Another option to implement a discrete time shift signal 1227 is by implementing a FIFO after the digital up converter. The data rate of the signal 1225 is by a factor F higher than the data rate of signal 1224, where F is the interpolation factor of the digital up converter. Adjusting the FIFO after the digital up-converter allows for smaller times steps.

Alternatively, the digital up conversion can be performed in the data source clock domain 1250. In this case the FIFO is then operated at a higher data rate and has therefore smaller time steps. This comes at the expense of a deeper FIFO to cover the required delay range. The phase accumulator value 1248 can be read out at the same time as the first value of the payload data D1 of the FIFO 1202, 1203. The phase accumulator value can be used to set the phase accumulator in the DUC 1204. This step assures that the DUC phase accumulator is always in sync with the data stream 1220, or, at least gets periodically corrected in case the TRX system gets disturbed. The phase accumulator value can be calculated in the data source.

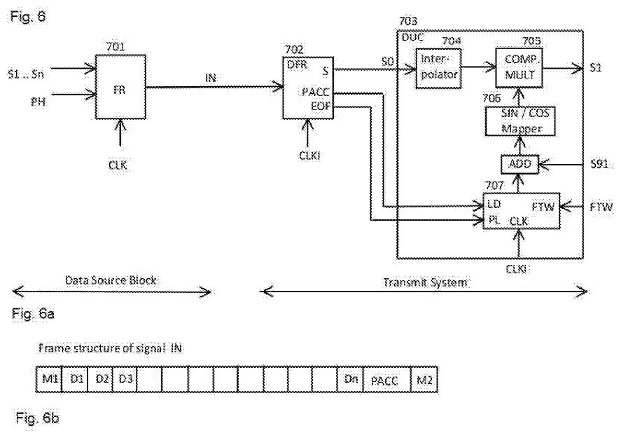

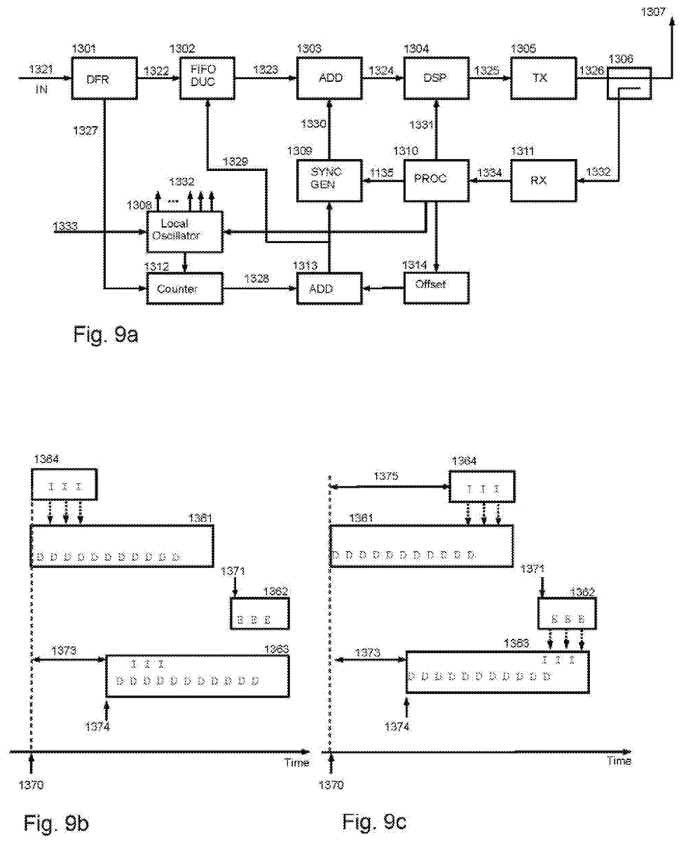

FIG. 9a depicts an embodiment of a transmit receive (TRX) system with digital up-conversion. The system uses the interference properties of an internally generated sync signal going to the antenna and external sync signal arriving at the antenna 1307. An observation path 1311 can detect the interference pattern of the internal sync signal and the external sync signal. The observation path 1311 can be the receiver of a transmit receive system, or, alternatively, the observation path of the transmitter's linearization loop. A counter 1312 establishes a local time for the TRX system. The counter can be reset to a known state based on signal 1327. Signal 1327 can be an external trigger signal or can be derived from the input data stream 1321 by the data frame receiver 1301. A possible frame structure is shown in FIG. 6a. The counter 1312 is clocked by a local oscillator 1308. The local oscillator can provide clock signals for all blocks in the system of FIG. 9a. The local oscillator can be locked to the frequency reference signal 1333 via a phase locked loop (PLL). The frequency reference signal 1333 can be derived from the data input signal 1321 or can be distributed via the antenna array. In case the reference signal 1333 comes from the antenna array, the reference signal 1333 would be generated by the processor 1310. The frequency reference signal 1333 assures that the TRX system is synchronized to a system frequency. The processor 1310 can activate the sync generator 1309 to add an internal sync signal to the digital RF signal 1323 to form a composite signal 1324. The sync signal can be added to the data stream 1323 at certain time offsets relative to the local time signal 1329. The processor 1310 will communicate to the sync generator 1309 to inject the sync signal at a specified time offset.

The internal sync signal 1330 can be orthogonal to an external sync signal which is received via antenna 1307. The sync signals can have other features to extract more information about the time shift between the sync signals. Coupling element 1306 can observe the interference behavior of the internal and external sync signal and form an analog interference signal 1332. The receive path 1311 will convert the analog interference signal into a digital interference signal 1334. The processor 1310 can adjust the local time 1329 and the delay of the digital signal processing block 1304 such that the interference between the internal sync signal and the external sync signal is a maximum. Maximum interference indicates that the external sync signal and the internal sync signal arrive at the coupling element 1306 at the same time. The sync signals can be designed such that they minimally interfere with the payload signals and still provide good observability of the interference behavior. The processor 1310 can adjust the local time 1329 by adding an offset value to the counter 1312. Using this mechanism the processor 1310 can time shift the signals 1323 in increments of one clock cycle. In order to make finer adjustments to the time shift the processor 1310 can adjust a digital delay filter in the DSP 1304. The processor 1310 could also adjust the phase of the local oscillator 1308 or the timing delay in the TX module 1305.

FIGS. 9b and 9c illustrate the process of aligning the internal sync signal 1364 to the external sync signal 1362. FIG. 9a depicts a scenario in which the external 1362 and internal sync signal 1364 are not aligned while FIG. 9b depicts a scenario in which the signals are aligned. The external sync signal arrives at time 1371 at the antenna. The payload data signal 1361 arrives at time 1370 at the TRX system and needs time 1373 to propagate to through the TRX system to arrive at the antenna. The sync signal 1364 is generated by the sync generator and added to the payload signal 1361 to form the composite RF signal 1363. In FIG. 9b the internal sync signal 1364 in the composite RF signal and the external sync signal don't interfere since they arrive at different times at the coupling element 1306. The processor 1310 will adjust the delay of the sync signal 1375 such that the interference of the external sync signal 1362 and the internal sync signal 1364 is a maximum.

The sync generator generates the sync signal in the digital domain. The adjustment of the sync signal delay can be achieved by inserting the sync signal at a different clock cycle in the payload signal 1361. For fine adjustments, the sync signal can be shifted by a digital delay filter it in the sync generator 1309. Once the optimal sync signal delay is determined the payload data stream can be delayed by the same amount using the FIFO 1302 and/or the DSP 1304.

Returning to FIG. 7a, in order to time align an array of multiple TRX system the following procedure can be used:

One TRX system is declared the master system and all other TRX systems in the array are declared slave systems. At the end of the calibration the slave systems will be aligned to the master system. The assignment of the master and the control of all the alignment steps can be controlled by a central controller in the data source module 1101. The procedure relies on the coupling between the antennas in the antenna array.

In a first step, the controller orders the master TRX system to add the internal sync signal to the payload signal. The internal sync signal of the master will act as external sync signal in the slaves.

In a second step, the controller orders a first TRX slave in the array to align the slave's internal sync signal to the external sync signal emitted by the master. Once the slave achieved alignment the slave will report to the controller the time offset 1375. The time offset is the time the slave TRX system needed to achieve maximal interference between the external and internal sync signal.

In a third step, the controller orders the first slave to add the internal sync signal to the payload signal at the original time, that is without the time offset 1375 from in the second step.

In a fourth step, the controller will order the master system to align the master's internal sync signal to the external sync signal transmitted by the first slave. The time offset will be reported back to the controller.

In a fifth step, the controller will calculate a time delay correction value from the time offset values reported by the master and the slave. Then, the controller will order the slave to delay its payload data by this amount.

The steps 1 to 5 are then repeated for the remaining slaves.

In order to best observe the interference behavior of the internal and external sync signal the sync signals should have substantially the same amplitude at the coupler. The external reference signal is generated in a neighboring TRX system, the coupling coefficients between the antennas are well known. Therefore, the power received at the coupler can be easily predicted and the power of the internal sync signal can be adjusted accordingly. Alternatively, the power of the internal and/or the external sync signal can be adjusted at the same time the aligning of the two signals is attempted. Instead of varying one parameter the search algorithm must now vary at least two parameters to find an optimal delay and power setting for the internal sync signal. In most application the payload signal has more power than the synchronization signal. In such application the technique of FIG. 4 can be applied in which before the observation path signal is converted back from the analog to the digital domain a replica of the payload signal is subtracted from the analog output signal. This step reduces the demand for dynamic range in the observation path and therefore makes the observability of the synchronization signals higher.

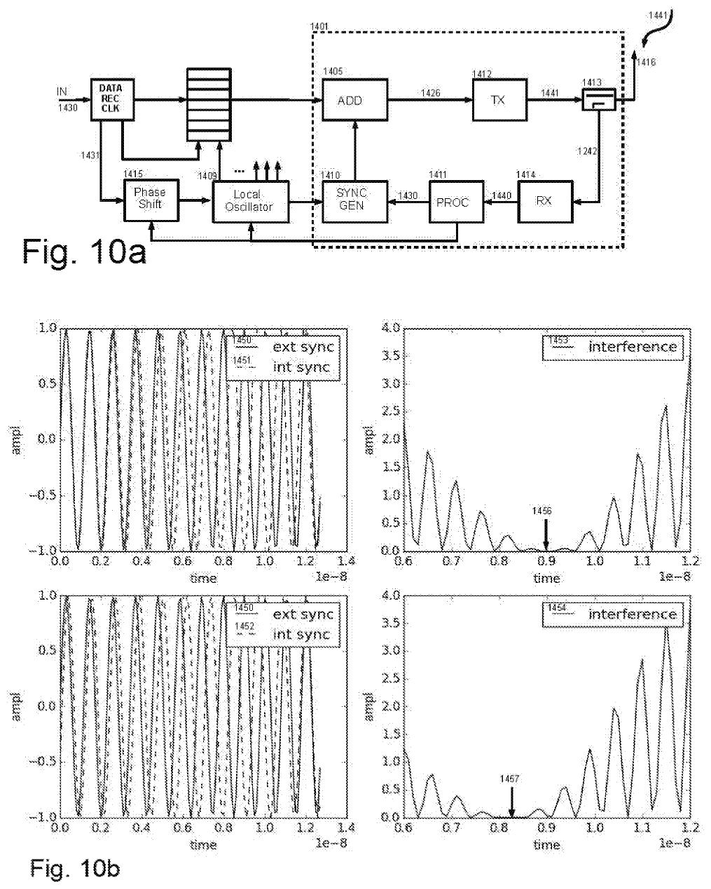

FIG. 10a depicts an embodiment of a phase comparator implementation. In conventional phase locked loop systems a reference clock is compared to a clock derived from an oscillator. The comparison of the reference clock to the derived clock is performed in a phase comparator. The phase comparator registers which clock edge arrives first at the phase comparator and generates either an up pulse or a down pulse which after a filtering process controls an oscillator. The pulse-width of the up and down pulse can be proportional to the phase difference between the reference clock and the derived clock. The up pulse will make the oscillator run faster while a down pulse will make the oscillator run slower.

In FIG. 10a the phase comparator 1401 compares the arrival of the internal sync signal to the external sync signal to determine if the local oscillator 1409 should run faster or slower. For example, the internal and external sync signal can be time limited waveforms as shown in FIG. 10b waveforms 1450 and 1451. In the example, waveform 1450 is a sine signal with constant amplitude and constant frequency. Waveform 1451 is a chirp signal with constant amplitude and a changing frequency. The two waveforms can be designed such that they are in phase with each other at the beginning and at the end of the waveform record and out of phase in the middle of the waveform record. Waveform 1450 can be generated by the sync generator 1410. Waveform 1451 can be generated by an external reference generator. This external reference generator can be the sync generator of a different TRX system in an antenna array. The interference between the internal and external sync signal, waveform 1453 will show a minimum at specific time 1456 within the record. If the external sync signal or the internal sync signal drift relative to each the interference minimum 1456 will move its position in the record. Waveform 1452 is a shifted version of waveform 1450 and time point 1457 is the new position of the minimum resulting from the phase shift. The receiver 1414 will observe the interference of the internal and external sync signal over a certain amount of time and pass the information to the processor 1411. The processor can analyze the record and determine if the minimum shifted to an earlier time point or a later time point and order the local oscillator 1409 to run either faster or slower in order to move the point of minimum interference back to its expected position and hence time aligning the internal sync signal to the external sync signal again. The processor 1411 can use a binary signal to control the local oscillator 1409 or use a multi bit signal to fine adjust the speed of the local oscillator. A loop controller, implemented in the processor 1411, can be used to control the local oscillator. The controller can be design to achieve a desired loop response behavior of the system. The local oscillator can be digitally controlled in order to avoid the conversion of the signal from the processor 1411 into an analog signal, as it would be necessary if the local oscillator 1409 is implemented as a voltage controlled oscillator.

The local oscillator 1409 can get the reference signal 1431 from signal 1430 generated by the data source. The data receiver will generate signal 1431 based on signal 1430. The local oscillator gets phase aligned to the signal 1431 and is synchronized to a systems clock common to the antenna array. In order to align the local oscillator 1409 to the external sync signal 1441 from the antenna a phase shifter 1415 can be added into the reference signal path 1431.

FIG. 10b is a simple example of the design of internal and external sync signals. Longer and/or more sophisticated sync signals can be designed to improve the observability of the alignment of the sync signals. An important criteria for the design of the sync signal is the observability of the interference between the external and internal sync signal and the resulting alignment information. Another criterion of the sync signal is the interference with the payload signal. Power, spectral properties and the frequency of the sync signals determine the interference with the payload signal and must be chosen such that they don't corrupt the payload signal.

With the disclosed circuits and methods a self-aligning array of individual transmit receive (TRX) systems can be built. The data to be transmitted by the individual can arrive at different times at individual TRX system. The TRX systems are capable of compensating the data arrival time differences and delivering the data time aligned to the antennas of the TRX systems. By observing the interference behavior of synchronization signal sent between the TRX systems, the TRX systems can be time aligned at the outputs.

The advantage of the described method is that no additional hardware components, like an additional calibration transmitter or receiver, are needed to align the array. To observe the interference behavior of the external sync signal and the internal sync signal the receiver of the TRX system or the observation path of the digital pre-distortion (DPD) loop can be used.

The many aspects and benefits of the invention are apparent from the detailed description, and thus, it is intended for the following claims to cover such aspects and benefits of the invention which fall within the scope and spirit of the invention. In addition, because numerous modifications and variations will be obvious and readily occur to those skilled in the art, the claims should not be construed to limit the invention to the exact construction and operation illustrated and described herein. Accordingly, all suitable modifications and equivalents should be understood to fall within the scope of the invention as claimed herein.

The above summary of the invention is not intended to describe each illustrated embodiment or every implementation of the present invention. The detailed description and claims that follow more particularly exemplify these embodiments.

The many aspects and benefits of the invention are apparent from the detailed description, and thus, it is intended for the following claims to cover such aspects and benefits of the invention, which fall within the scope, and spirit of the invention. In addition, because numerous modifications and variations will be obvious and readily occur to those skilled in the art, the claims should not be construed to limit the invention to the exact construction and operation illustrated and described herein. Accordingly, all suitable modifications and equivalents should be understood to fall within the scope of the invention as claimed herein.

Various embodiments of systems, devices and methods have been described herein. These embodiments are given only by way of example and are not intended to limit the scope of the invention. It should be appreciated, moreover, that the various features of the embodiments that have been described may be combined in various ways to produce numerous additional embodiments. Moreover, while various materials, dimensions, shapes, configurations and locations, etc. have been described for use with disclosed embodiments, others besides those disclosed may be utilized without exceeding the scope of the invention.

Persons of ordinary skill in the relevant arts will recognize that the invention may comprise fewer features than illustrated in any individual embodiment described above. The embodiments described herein are not meant to be an exhaustive presentation of the ways in which the various features of the invention may be combined. Accordingly, the embodiments are not mutually exclusive combinations of features; rather, the invention can comprise a combination of different individual features selected from different individual embodiments, as understood by persons of ordinary skill in the art. Moreover, elements described with respect to one embodiment can be implemented in other embodiments even when not described in such embodiments unless otherwise noted. Although a dependent claim may refer in the claims to a specific combination with one or more other claims, other embodiments can also include a combination of the dependent claim with the subject matter of each other dependent claim or a combination of one or more features with other dependent or independent claims. Such combinations are proposed herein unless it is stated that a specific combination is not intended. Furthermore, it is intended also to include features of a claim in any other independent claim even if this claim is not directly made dependent to the independent claim.

Any incorporation by reference of documents above is limited such that no subject matter is incorporated that is contrary to the explicit disclosure herein. Any incorporation by reference of documents above is further limited such that no claims included in the documents are incorporated by reference herein. Any incorporation by reference of documents above is yet further limited such that any definitions provided in the documents are not incorporated by reference herein unless expressly included herein.

For purposes of interpreting the claims for the present invention, it is expressly intended that the provisions of Section 112(f) of 35 U.S.C. are not to be invoked unless the specific terms “means for” or “step for” are recited in a claim.

1. A signal processing circuit comprising:
a local oscillator configured to generate clock signals;
a FIFO configured to receive an input data signal and generate a first digital signal;
a sync reference generator configured to generate an internal sync signal;
an combiner configured to combine the internal sync signal and the first digital signal to generate a composite signal;
a transmitter configured to receive the composite signal and generate an analog output signal;
a coupling element configured to receive the analog output signal and the external sync signal and generate an analog receive signal;
a receiver configured to receive the analog receive signal and generate a digital receive signal; and
a processor configured to receive the digital receive signal and control one or more of the local oscillator, FIFO, adder, transmitter, receiver, and sync reference generator.

2. The signal processing circuit of claim 1, further comprising:
a data receiver configured to receive a composite data stream with embedded clocking information and generate the input data signal and a data clock signal;
and wherein the input side of the FIFO is controlled by the data clock signal.

3. The signal processing circuit of claim 1, further comprising:
a digital signal processor configured to receive the composite signal from the combiner and generated a second composite signal to be received by the transmitter;
and wherein the digital signal processor is capable of shifting the signal the second composite signal in time relative to the composite signal.

4. The signal processing circuit of claim 1, further comprising a digital up converter configured to receive the first digital signal and generate second digital signal, wherein the second digital signal is received by the combiner.

5. The signal processing circuit of claim 4, further comprising a data receiver configured to receive a frame based data stream comprising one or more frames, wherein each of the one or more frames comprises payload data and a phase accumulator value, and wherein the digital up converter comprises a phase accumulator and wherein the phase accumulator is updated with the received phase accumulator value.

6. The signal processing circuit of claim 1, wherein interference between the internal sync signal embedded in the analog output signal and the external sync signal can be observed by the circuit.

7. The signal processing circuit of claim 6, wherein the processor can detect the time relation between the internal sync signal and the external sync signal.

8. The signal processing circuit of claim 7,
wherein the external sync signal and internal sync signal are designed such that the processor can detect the amount of time shift from the external sync signal to the internal sync signal.

9. An antenna array comprising:
a plurality of signal processing units wherein each of the plurality of signal processing units comprises:
a local oscillator configured to generate clock signals;
a FIFO configured to receive an input data signal and generate a first digital signal;
a sync reference generator configured to generate an internal sync signal;
an combiner configured to combine the internal sync signal and the first digital signal to generate a composite signal;
a transmitter configured to receive the composite signal and generate an analog output signal;
a coupling element configured to receive the analog output signal and the external sync signal and generate an analog receive signal;
a receiver configured to receive the analog receive signal and generate a digital receive signal; and
a processor configured to receive the digital receive signal and control one or more of the local oscillator, FIFO, adder, transmitter, receiver, and sync reference generator; and
wherein the internal sync signal of one of the plurality of signal processing circuits can generate the external sync signal for the other signal processing units.

10. The antenna array of claim 9, further comprising,
an array controller;
wherein the array controller activates and deactivates the internal sync signals in each of the plurality of signal processing units and instructs each of the plurality of signal processing units to adjust each local oscillator and/or digital signal processor such that the analog output signals generated by each of the plurality of signal processing units are time aligned.

11. A method for calibrating a transmitter array comprising:
in a master TRX system, generating a master internal sync signal, adding the master internal sync signal to a master payload signal to form a master composite signal, and transmitting the master composite signal according to a master time base;
in each of one or more slave TRX systems, generating a slave internal sync signal, adding a slave internal sync signal to a slave payload signal to form a slave composite signal, transmitting the slave composite signal according to a slave time base and an observed interference behavior of the master interference signal embedded in the master composite signal and the slave interference signal embedded in the slave composite signal at the master TRX system and the slave TRX system; and
adjusting the slave time base such that the master payload signal and the slave payload signal are transmitted at the same time.

12. The method of claim 11, further comprising:
adjusting a delay of the master internal sync signal relative to the master time base and the slave internal sync signal relative to the slave time base to compute the time difference between the master time base and the slave time base.

13. The method of claim 11, further comprising:
in the master and slave TRX systems, receiving a plurality of data signals and up converting the plurality of data signals to form the master and slave payload signals.

14. The method of claim 13, further comprising
in the master and slave TRX systems, receiving a plurality of frame structured signals containing the master and slave payload signals and a plurality of phase accumulator values; and
up converting the plurality of payload signals based on the plurality of phase accumulator values.

15. The method of claim 11, further comprising
designing each of the internal sync signals such that the a value corresponding to the time shift between the internal sync signals can be computed.
